(19) United States
(12) Patent Application Publication
(10) Pub. No.: US 2013/0063912 A1
(43) Pub. Date: Mar. 14, 2013

(54) COF PACKAGING METHOD AND STRUCTURE FOR LCD DRIVER CHIPS

(71) Applicants: Liang-Chan Liao, Shenzhen (CN); Po-Shen Lin, Shenzhen (CN); Yu Wu, Shenzhen (CN)

(72) Inventors: Liang-Chan Liao, Shenzhen (CN); Po-Shen Lin, Shenzhen (CN); Yu Wu, Shenzhen (CN)

(21) Appl. No.: 13/377,789

(22) PCT Filed: Oct. 1, 2011
(86) PCT No.: PCT/CN11/80510

§ 371 Date: Dec. 12, 2011

(30) Foreign Application Priority Data
Sep. 14, 2011 (CN) 201110272699.3

(51) Int. Cl. H05K 7/06; H05K 13/04

(52) U.S. Cl. 361/760; 29/592.1

(57) ABSTRACT

A COF packaging method and structure for LCD driver chips, the packaging structure comprises a substrate tape and a plurality of COF packaging units arranged consecutively along a direction the substrate tape is moved. Each of the packaging units includes a LCD driver chip, and a first lead and a second lead electrically connected to the LCD driver chip and distributed along two sides of the LCD driver chip. The LCD driver chip of each of the packaging units is parallel to the moving direction of the substrate tape, the first lead and the second lead of each of the packaging units are extended along a width of the substrate tape. By the method, the number and intervals of the leads are not limited by the width dimension of the substrate tape, in order to suit the requirements of large-sized liquid crystal panels.

### FIELD OF THE INVENTION

The present invention relates to manufacturing process of liquid crystal display, and more particularly to a packaging method and structure for LCD driver chips used in the manufacturing process of liquid crystal display.

### BACKGROUND OF THE INVENTION

Packaging of LCD driver chips requires high density bonding technology, existing packaging structures mainly include TAB (Tape Automated Bonding), COG (Chip On Glass) and COF (Chip on Flex). TAB is usually a triple layer structure with polyimide (PI) used as a substrate, and the polyimide substrate is bonded with copper foil by an adhesive. An ILB (Inner Lead Bonding) portion which is a side connected to a PCB (Printed Circuit Board), is bonded using eutectic bonding technology, and under-filled with epoxy to protect the bonding structure. On the other hand, the OLB (Outer Lead Bonding) portion which is a side connected to a glass base-plate, is bonded using plastic strip bonding technology. For COG, IC dies are directly adhered on a glass base-plate circuit by flip-chip bonding technology. Although the cost for taping is saved, nevertheless, the entire base-plate will be failed with only one IC die being mishandled; therefore, it is seldom used for large-sized liquid crystal panels. COF is an improved structure from TAB, which is a dual layer flexible plate without the middle adhesive layer of TAB; therefore, it is thinner and more flexible with better flexibility; basically it employs flip chip bonding technology to have one or a plurality of IC dies, passive and active components packaged on a tape.

Referring to FIG. 1 which shows an existing COF packaging structure of a LCD driver chip, an entire roll of tape is rolled and feed, and it mainly comprises a substrate tape 1a with a plurality of pilot holes evenly disposed on its both sides, the substrate tape 1a is usually 35 mm or 48 mm wide; and a plurality of COF packaging units 2a is arranged consecutively along a direction the tape is moved. Each of the COF packaging units includes: a LCD driver chip 21a is disposed on the substrate tape 1a horizontally and perpendicular to the moving direction of the tape; a lead 22a on a PCB side for connecting to an inner lead which has less leads, and is arranged on one side of the LCD driver chip 21a, for example a front side; a lead 23a on a glass base-plate side for connecting to an outer lead which has more leads, and is arranged on another side of the LCD driver chip 21a, for example a back side. This type of structure is limited by the width of the substrate tape 1a. As large-sized LCD panels require LCD driver chips with high integration density, when there are more and more channels in a LCD driver chip, the number of leads on a base-plate side is also increased, thus the pitches between the leads are getting smaller and smaller; therefore, the requirement for LCD driver chips and packaging techniques is also higher, this will affect the yield rate of packaging.

### SUMMARY OF THE INVENTION

The present invention relates to manufacturing process of liquid crystal display, and more particularly to a packaging method and structure for LCD driver chips used in the manufacturing process of liquid crystal display.

In order to tackle the problem of existing technical deficiency, the present invention provides a COF packaging method and structure for LCD driver chips, so as not to be limited by the width dimension of the substrate tape, in order to suit the requirements of large-sized liquid crystal panels.

Technical projects employed by the present invention to tackle the abovementioned technical problems include, providing a COF packaging method for LCD driver chips, it includes: a substrate tape is disposed and a plurality of COF packaging units is arranged on the tape and consecutively along a moving direction of the tape, so that each of the packaging units includes a LCD driver chip, and a first lead and a second lead which are electrically connected to the LCD driver chip and distributed along two sides of the LCD driver chip. Therefore, the LCD driver chip of each of the packaging units is parallel to the direction the substrate tape is moved, and so that the first lead and the second lead of each of the packaging units are extended along a width of the substrate tape.

The technical projects employed by the present invention to tackle the abovementioned technical problems further include, providing a COF packaging structure for LCD driver chips, it includes a substrate tape and a plurality of COF packaging units arranged consecutively along a moving direction of the tape, and each of the packaging units includes a LCD driver chip, and a first lead and a second lead which are electrically connected to the LCD driver chip and distributed along two sides of the LCD driver chip.

The LCD driver chip of each of the packaging units is parallel to the direction the substrate tape is moved, and the first lead and the second lead of each of the packaging units are extended along a width of the substrate tape.

In comparing to conventional techniques, a COF packaging method and structure for LCD driver chips, by having the LCD driver chip disposed vertically to the width of the substrate tape, so that the leads can be extended along the width of the substrate tape, and the number and intervals of the leads will not be limited by the width dimension of the substrate tape, in order to suit the requirements of large-sized liquid crystal panels.

### BRIEF DESCRIPTION OF THE DRAWINGS

FIG. 1 is an illustration of a COF packaging structure of a LCD driver chip of a prior art; and

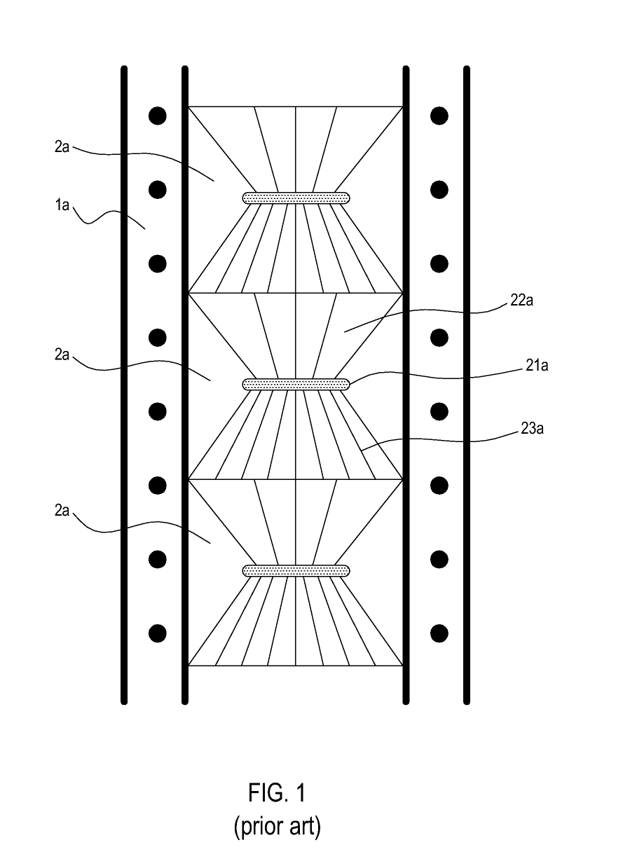

FIG. 2 is an illustration of a COF packaging structure of a LCD driver chip of the present invention.

### DETAILED DESCRIPTION OF THE INVENTION

The present invention will become more fully understood by reference to the following detailed description thereof when read in conjunction with the attached drawings.

A COF packaging method of a LCD driver chip of the present invention is achieved by having the LCD driver chip of each of the packaging units disposed parallel to the moving direction of the substrate tape, which is vertical to the width of the substrate tape, and having the first lead and the second lead of each of the packaging units, which are electrically connected to the LCD driver chip and distributed along the two sides of the LCD driver chip, extended along the width of the substrate tape, so that the number and intervals of the leads are not limited by the width dimension of the substrate tape.

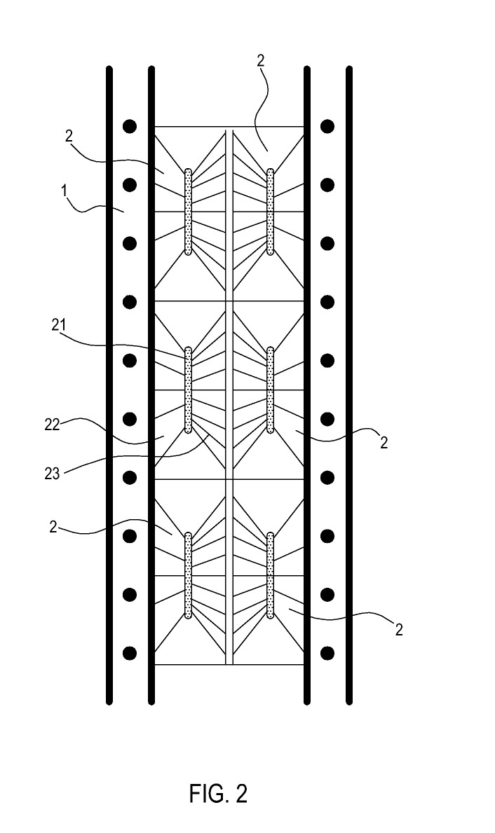

Referring to FIG. 2, it shows an embodiment of a COF packaging structure of a LCD driver chip embodied by a COF packaging method of the present invention. It mainly comprises a substrate tape 1, and a plurality of COF packaging units 2 arranged consecutively along a moving direction of the substrate tape 1.

Each of the packaging units 2 includes a LCD driver chip 21, and a first lead 22 and a second lead 23 which are electrically connected to the LCD driver chip 21 and distributed along two sides of the LCD driver chip 21, for connecting an inner lead and an outer lead respectively. The LCD driver chip 21 of each of the packaging units 2 is parallel to the direction the substrate tape 1 is moved, and the first lead 22 and the second lead 23 of each of the packaging units 2 are extended along a width of the substrate tape 1. For this type of structure, a width of each of the packaging units 2 is no longer interrelated to the width of the substrate tape 1, and the width can be designed according to the number of channels, so that the problem of small intervals between the leads can be avoided, in order to meet the requirements of manufacturing, thus the costs for equipment upgrade can be saved.

Taken into consideration of the long and narrow strip structure of each of the packaging units 2, when two of the packaging units 2 can be accommodated in parallel by the width dimension of the substrate tape 1 as shown in FIG. 2, then two of the packaging units 2 can be disposed in parallel in order to save a COF packaging length of the LCD driver chip 21, and the efficiency of operation can also be enhanced.

It should be noted that for convenience of detachment of the two parallel disposed packaging units 2, an appropriate interval should be maintained between them. Taken into consideration the second lead 23 is more meticulous and delicate, and the first lead 22 is relatively more sparse; therefore, when the two packaging units 2 are disposed in parallel, the best is to have the first lead 22 disposed closed to an outer side of the substrate tape 1, while the second lead 23 disposed closed to a middle of the substrate tape 1; so that the second lead 23 can be protected from damages such as because of uneven force exerted on the substrate tape 1 during transportation.

In comparing to conventional techniques, a COF packaging method and structure for LCD driver chips, by having the LCD driver chip 21 disposed vertically to the width of the substrate tape 1, and having the first lead 22 and the second lead 23 which are electrically connected to the LCD driver chip 21 and distributed along the two sides of the LCD driver chip 21, extended along the width of the substrate tape 1, so that the number and intervals of the first lead 22 and the second lead 23, especially the second lead 23 which is for connecting the outer lead, are not limited by the width dimension of the substrate tape 1; in addition, by having two of the packaging units 2 disposed in parallel, an overall length of the substrate tape 1 can be saved in order to have the efficiency of operation enhanced. Thereby, the demand for manufacturing of large-sized liquid crystal panels can be met with lower equipment costs.

Note that the specifications relating to the above embodiments should be construed as exemplary rather than as limitative of the present invention, with many variations and modifications being readily attainable by a person of average skill in the art without departing from the spirit or scope thereof as defined by the appended claims and their legal equivalents.

What is claimed is:

1. A COF packaging method for a LCD driver chip, comprising:
disposing a substrate tape; and
arranging a plurality of COF packaging units consecutively along a moving direction of the substrate tape,
wherein each of the packaging units including a LCD driver chip, and a first lead and a second lead electrically connected to the LCD driver chip and distributed along two sides of the LCD driver chip, and wherein the LCD driver chip of each of the packaging units is parallel to the moving direction of the substrate tape, and so that the first lead and the second lead of each of the packaging units are extended along a width of the substrate tape.

2. The COF packaging method as claimed in claim 1, wherein disposing of two of the packaging units in parallel along the width of the substrate tape.

3. The COF packaging method as claimed in claim 2, wherein setting an interval between the two parallel disposed packaging units.

4. The COF packaging method as claimed in claim 2, wherein connecting the first lead to an inner lead, connecting the second lead to an outer lead, and disposing the first lead on an outer side of the substrate tape.

5. A COF packaging structure of a LCD driver chip, comprising:
a substrate tape ; and
a plurality of COF packaging units arranged consecutively along a moving direction of the substrate tape, wherein each of the packaging units including a LCD driver chip, and a first lead and a second lead electrically connected to the LCD driver chip and distributed along two sides of the LCD driver chip,
wherein the LCD driver chip of each of the packaging units is parallel to the moving direction of the substrate tape, and the first lead and the second lead of each of the packaging units are extended along a width of the substrate tape.

6. The COF packaging structure as claimed in claim 5, wherein two of the packaging units are disposed in parallel along the width of the substrate tape.

7. The COF packaging structure as claimed in claim 6, wherein an interval is set between the two parallel packaging units.

8. The COF packaging structure as claimed in claim 6, wherein the first lead is connected to an inner lead, the second lead is connected to an outer lead, and the first lead is disposed on an outer side of the substrate tape.
